(19) United States
(12) Patent Application Publication
(10) Pub. No.: US 2024/0312944 A1
(43) Pub. Date: Sep. 19, 2024

(54) Semiconductor Die and Method for Attaching a Semiconductor Die to a Solid Structure with Controlled Fillet Height

(71) Applicant: TE Connectivity Solutions GmbH, Schaffhausen (CH)

(72) Inventors: Kaspar Jenni, Muhlenstrasse (CH); Ismael Brunner, Schaffhausen (CH); Thomas Arnold, Schaffhausen (CH)

(73) Assignee: TE Connectivity Solutions GmbH, Schaffhausen (CH)

(21) Appl. No.: 18/604,807

(22) Filed: Mar. 14, 2024

(30) Foreign Application Priority Data
Mar. 17, 2023 (EP) 23162600.3

(51) Int. Cl. H01L 23/00; B81B 3/00

(52) U.S. Cl. CPC H01L 24/29; B81B 3/0021; H01L 24/32; H01L 24/83; B81B 2201/0235; B81B 2201/0264; B81B 2203/0127; H01L 2224/26145; H01L 2224/32225; H01L 2224/8385

(57) ABSTRACT

A semiconductor die includes a top side, a bottom side opposite to the top side, and a side surface connecting the top side and the bottom side. The bottom side and a part of the side surface are attachable to a solid structure by a die attach material. The side surface has an attachment control element defining an attachment zone contacted by the die attach material and/or an exclusion zone that is not contacted by the die attach material.

### CROSS-REFERENCE TO RELATED APPLICATIONS

This application claims the benefit of the filing date under 35 U.S.C. § 119(a)-(d) of European Patent Application No. 23162600.3, filed on Mar. 17, 2023.

### FIELD OF THE INVENTION

The present invention relates to a semiconductor die and, more particularly, to a semiconductor die attached to a solid structure.

### BACKGROUND

Semiconductor dies may contain integrated circuits, sensor elements, or other components. A semiconductor die is usually separated from a wafer by a process called dicing. Subsequently, a semiconductor die may be fixed to a solid structure, such as a substrate, a package, or a lead frame. For fixing the semiconductor die to the solid structure, a die attach material is used. Die attach material may be a glue, in particular a glue comprising epoxy, silicone or other materials. Furthermore, the die attach material may comprise particles, for example particles configured to increase heat conductivity between the semiconductor die and the solid structure.

When a semiconductor die is attached to a solid structure and die attach material is applied between the semiconductor die and the solid structure, the die attach material may form a fillet at the side surface of the semiconductor die. The height of said fillet may define to what extend the side or sides of the semiconductor die are fixed to the solid structure. A large fillet height may improve the fixation of the semiconductor die to the solid structure, but also increases mechanical stress on the semiconductor die. If, for example, the solid structure is under mechanical stress due to CTE (coefficient of thermal expansion) mismatch, this mechanical stress may be carried into the semiconductor die via the die attach material (when the die attach material is in a solid state). A low fillet height may reduce mechanical stress carried from the solid structure into the semiconductor die, but may provide insufficient mechanical stability of the fixation of the semiconductor die to the solid structure. There is a need for control of the fillet height when the semiconductor die is attached to a solid structure.

### SUMMARY

A semiconductor die includes a top side, a bottom side opposite to the top side, and a side surface connecting the top side and the bottom side. The bottom side and a part of the side surface are attachable to a solid structure by a die attach material. The side surface has an attachment control element defining an attachment zone contacted by the die attach material and/or an exclusion zone that is not contacted by the die attach material.

### BRIEF DESCRIPTION OF THE DRAWINGS

The invention will be described in more detail in the following with reference to exemplary embodiments illustrated in the drawings, in which:

FIG. 1 is a schematic sectional view of a semiconductor die on a solid structure without an attachment control element;

FIG. 2 shows a first embodiment of a semiconductor die with an attachment control element formed as a step in a cross-sectional view;

FIG. 3 shows a second embodiment of a semiconductor die with attachment control elements formed as steps in a cross-sectional view;

FIG. 4 shows a third embodiment of a semiconductor die with attachment control elements formed as steps in a cross-sectional view;

FIG. 5 shows an embodiment of a semiconductor die with a functionalized surface in a cross-sectional view;

FIG. 6 shows another embodiment of a semiconductor die with a functionalized surface in a cross-sectional view;

FIG. 7 shows an embodiment of a semiconductor die with a functionalized surface in combination with attachment control elements formed as steps in a cross-sectional view;

FIG. 8 shows another embodiment of a semiconductor die with a functionalized surface in combination with attachment control elements formed as steps in a cross-sectional view; and

FIG. 9 shows an embodiment of a semiconductor die with spacers in a cross-sectional view.

### DETAILED DESCRIPTION OF THE EMBODIMENT(S)

In the following, the invention and its improvements are described in greater detail using exemplary embodiments with reference to the drawings. The various features shown in the embodiments may be used independently of each other in specific applications. In the following figures, elements having the same function and/or the same structure will be referenced by the same reference signs.

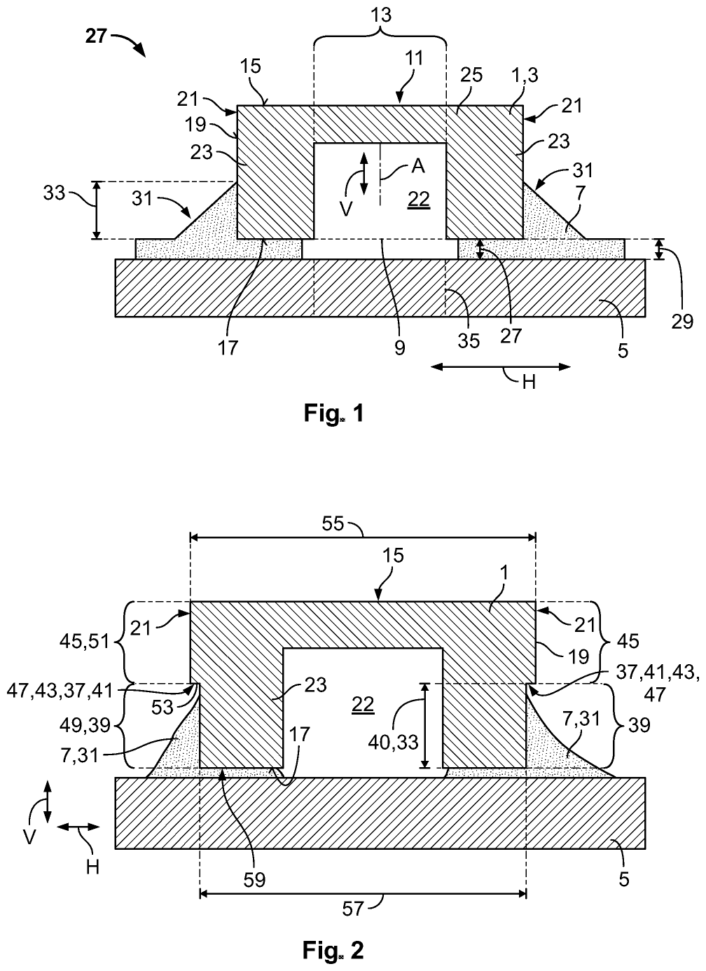

In the following, reference is made to FIG. 1. FIG. 1 only serves for explanatory reasons. FIG. 1 shows a semiconductor die 1 attached to a solid structure 5 via a die attach material 7 in a cross-sectional view. The solid structure 5 may be a substrate, a package, or any other suitable solid structure configured to carry the semiconductor die.

The semiconductor die 1 may have an overall rectangular cubic shape 9, which is indicated by the dashed line in FIG. 1. This may be the case, for example, when the semiconductor die 1 comprises integrated circuits or other electronic structures. The semiconductor die 1 according to the invention, which will be described later on with respect to FIGS. 2 to 9, may be a micro-electromechanical system (MEMS), in particular a MEMS sensor device 3 such as for a pressure sensor, a force sensor, or an accelerometer, and is thus provided with a membrane 11 in a central region 13 of the semiconductor die 1. The membrane 11 may contain or support piezoresistive elements, a piezoelectric membrane or a membrane forming a capacitive element.

The semiconductor die 1 has a top side 15 and a bottom side 17 opposite to the top side 15. The top side 15 and the bottom side 17 are connected via a side surface 19, which may extend continuously around the semiconductor die 1, around a central axis A of the semiconductor die 1.

The semiconductor die 1 may have four planar sides 21, in particular in case of a rectangular cubic shape 9. However, as the sides 21 are interconnected with each other, they have a common continuous side surface 19.

The semiconductor die 1 may have an overall II-shaped cross-section. Thus, the semiconductor die 1 may have an overall cup shape having a recess 22 that extends into the bottom side 17, as shown in FIG. 1. The II-shaped cross-section of the semiconductor die 1 may be formed by two legs 23, which are spaced apart from each other along a horizontal direction H and which extend parallel to each other and with a vertical direction V. The two legs 23 are interconnected by a web 25 that extends parallel to the horizontal direction H and perpendicular to the legs 23. The membrane 11 may form or be part of the web 25. Between the web 25 and the legs 23, the recess 22 is located. The terms “leg” and “web” refer to the cross-section only. In particular, in an overall cup shape semiconductor die, the legs 23 in the cross-section may be formed by walls that form the sides 21, while the web 25 may be formed by a top plate or by the membrane 11.

The semiconductor die 1 is fixed on the solid structure 5 by the die attach material 7, as shown in FIG. 1. In an embodiment, in order to assemble the arrangement comprising the solid structure 5 and the semiconductor die 1, the die attach material 7 is applied in the liquid phase onto the solid structure 5. Subsequently, the semiconductor die 1 is placed on the die attach material 7.

By applying a predefined pressure onto the semiconductor die 1, a distance 27 between the semiconductor die 1 and the solid structure 5 can be defined during the arrangement of the semiconductor die 1 on the solid structure 5. This distance 27 corresponds to a thickness 29 of the layer of die attach material 7 between the semiconductor die 1 and the solid structure 5. This thickness 29 is also known as “bond line thickness” (BLT).

In the liquid phase of the die attach material 7, the die attach material 7 tends to climb up the side surfaces 19 of the semiconductor die 1 and wets the side surface 19. Thereby, a fillet 31, shown in FIG. 1, is formed around the semiconductor die 1. Depending on the surface energy and of the properties of the die attach material 7, the fillet 31 extends up to a certain height; a fillet height 33.

The fillet height 33 is important for the semiconductor die 1. The semiconductor die 1 needs to be securely fixed to the solid structure 5. Thus, the fillet height 33 should not be too low. Conversely, the higher the fillet height 33, the more mechanical stress may be introduced from the solid structure 5 into the semiconductor die 1. In particular, in case of a semiconductor die 1 having a membrane 11, this may lead to erroneous measurements as the mechanical stress induced via the die attach material 7 into the semiconductor die 1 may be interpreted as pressure on the membrane containing piezoresistive elements 11.

In case of a semiconductor die 1 for a MEMS sensor device 3, the solid structure 5 may have a through hole 35, which is indicated by dashed lines in FIG. 1. This through hole 35 may open a channel to the bottom side 17, in particular into the recess 22. Thus, a fluid communication between an outside medium and the membrane 11 may be achieved.

An object of the invention is to control the fillet height 33. In the following, different embodiments of a semiconductor die 1 according to the invention are described with respect to FIGS. 2 to 9. For the sake of brevity, only the differences with respect to the semiconductor die 1 described with respect to FIG. 1 are mentioned.

A first embodiment of a semiconductor die 1 according to the invention is described with respect to FIG. 2. In the side surfaces 19 of the semiconductor die 1, an attachment control element 37 is formed. The attachment control element 37 may extend circumferentially around the semiconductor die 1. Alternatively, each side 21 may be provided with an attachment control element 37. In an embodiment, the attachment control element 37 extends around the semiconductor die 1 parallel to the horizontal direction H. The central region 13 may be the center of a plane defined by top and bottom sides. The central region 13 may be arranged radially in the center of the semiconductor die 1, in particular spaced apart horizontally from at least one attachment control element 37.

The attachment control element 37 defines where die attach material 7 wets the side surfaces 19. In particular, the attachment control element 37 defines an attachment zone 39 of the side surfaces 19 that is to be contacted by the attach material 7. The attachment zone 39 extends around the semiconductor die 1 along its circumference parallel to the horizontal direction H. In the vertical direction V, the attachment control element 37 defines the border of the attachment zone 39. Thereby, a maximum height 40 is defined. If the die attach material 7 spreads up to this maximum height 40, the maximum height 40 may be identical to the fillet height 33.

The attachment control element 37 is a stop element 41 for the die attach material 7. Thus, the attachment control element 37 may prevent the die attach material 7 form further spreading in the vertical direction V on the side surface 19. In particular, the attachment control element 37 forms a physical barrier 43. The attachment control element 37 does not only define an attachment zone 39, but also an exclusion zone 45 that is not to be contacted by the die attach material 7. As the attachment control element 37 acts as a stop element for the die attach material 7 along the vertical direction V, it excludes or stops the die attach material 7 form spreading into the exclusion zone 45.

The attachment control element 37 may be formed as a step 47, as shown in FIG. 2. The step 47 extends between two vertical sections 49 and 51 of the side surfaces 19. The first vertical section 49 is closer to the bottom side 17 and may be identical to the attachment zone 39. A second vertical section 51 extends along the vertical direction V from the attachment control element 37 to the top side 15 and may be identical to the exclusion zone 45.

The step 47 comprises a horizontal section 53, which extends parallel to the horizontal direction H. From the first vertical section 49, the horizontal section 53 of the step 47 extends outwardly and perpendicular to the vertical section 49.

The horizontal section 53 is followed by the vertical section 51, which extends perpendicular to the horizontal section 53. Thereby, the semiconductor die 1 may have a larger diameter 55 in the region of vertical section 51 compared to the diameter 57 in the region of vertical section 49. In other words, the semiconductor die 1 may have an overall mushroom shape.

In an embodiment, the step 47 introduces two sharp edges into the side surface 19. The sharp edges may form essentially right angles. To be sharp enough, the edges may have radii below 50 μm.

In an embodiment, the die attach material 7 is in contact with the semiconductor die 1 in the attachment zone 39 or, if present, in the attachment zone 39 and at a bottom surface 59 of the semiconductor die 1. The bottom surface 59 may be located at the free ends of the legs 23.

Die attachment material 7 between a bottom surface 59 and the solid structure 5 may extend continuously along the circumference of the semiconductor die 1 along the horizontal direction H. Thereby, the recess 22 or the volume defined by the recess 22 may be sealed to the outside.

In the following, a second advantageous embodiment of the semiconductor die 1 is described with respect to FIG. 3. Again, only the differences to the semiconductor die 1 described with respect to FIG. 1 and to the first embodiment of the invention described with respect to FIG. 2 are mentioned.

In addition to the step 47, which may be similar to the one described with respect to FIG. 2, the inner sides 61 of the legs 23 are also provided with inner steps 63 that act as physical barriers 43 and thus form attachment control elements 37 configured as stop elements 41.

By way of example, in the embodiment of FIG. 3, the inner steps 63 are shown mirror-symmetrically to the steps 47 and on the same height as these along the vertical direction V. However, this is not mandatory. The inner steps 63 may be located at a different position along the vertical direction V and may also differ in size from the steps 47 on the side surfaces 19. The inner steps 63 may define additional attachment zones 39. The inner steps 63 may prevent die attachment material from reaching the membrane 11.

In the embodiment shown in FIG. 3, die attach material 7 contacts the semiconductor die 1 in the attachment zones 39 on the side surfaces 19, the bottom surfaces 59 and the attachment zones 39 on the inner sides 61 of the legs 23. This may improve the fixation of the semiconductor die 1 to the solid structure 5.

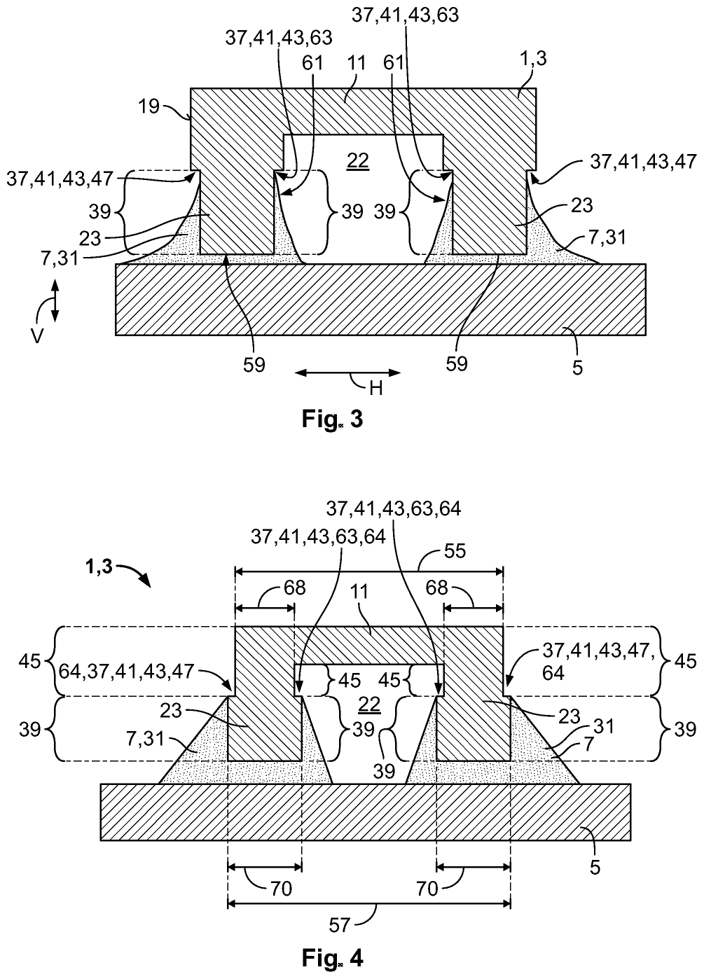

Reference is now made to FIG. 4, in which a further advantageous embodiment of a semiconductor die 1 according to the invention is shown. As an alternative to the shape of the semiconductor die 1 described above with respect to FIGS. 2 and 3, the steps 47 and 63 have inverse shapes. In other words, the diameter 55 is smaller than the diameter 57. Further, each leg 23 has a diameter 70 in the region of the attachment zone 39 that is bigger than a diameter 68 in the region of the exclusion zone 45. The step 47 and 63 thus form terrace-like structures 64. These structures 64 may hinder die attach material 7 from spreading further upwards along the vertical direction V.

In contrast to the embodiments of the semiconductor die 1 described with respect to FIGS. 2 to 4, the semiconductor die 1 of FIG. 5 does not comprise an attachment control element 37 that is formed as a physical barrier 43, but as a region 65 having increased wettability for the die attach material 7. In the region 65, wettability of the side surface 19 and bottom surfaces 59 is increased compared to an adjacent region 67 of the side surface 19.

The region 65 may comprise a functionalized surface 66. Surface functionalization to form the functionalized surface 66 may be achieved by typical methods such as coating, etching, layer deposition or others. By way of example, atomic layer deposition (ALD), physical vapor deposition (PVD), chemical vapor deposition (CVD), plasma enhanced chemical vapor deposition (PECVD) or other methods may be used for the deposition of layers. In the region 65, the side surface 19 and bottom surface 59 may have an increased surface energy.

In the embodiment shown in FIG. 5, the die attach material 7 may only contact the semiconductor die 1 in the region 65. The region 65 may form the attachment zone 39. The region 67 of the side surface 19 may thus form the exclusion zone 45. The region 65 may define a maximum height 40 up to which the die attach material 7 may contact the semiconductor die 1 in the vertical direction V. Thereby, the fillet height 33 may be defined.

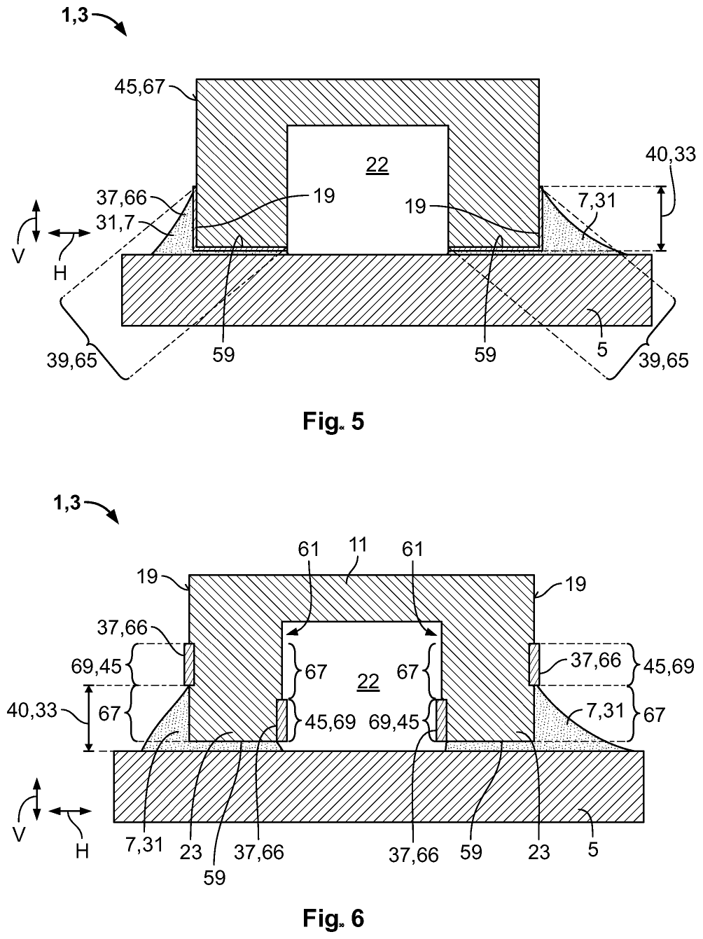

FIG. 6 shows another embodiment of the semiconductor die 1 according to the invention, which utilizes surface functionalization for forming attachment control elements 37. In contrast to the embodiment described with respect to FIG. 5, the embodiment shown in FIG. 6 comprises attachment control elements 37 formed as functionalized surfaces 66 in regions 69 configured to reduce the wettability for the die attach material 7.

In the regions 69, the surface of the semiconductor die I may have a reduced surface energy compared to adjacent surface regions 67. Here too, the surface functionalization may be achieved by typical methods as mentioned above. The regions 69 form exclusion zones 45 that may hinder the die attach material 7 from contacting these regions 69.

In an embodiment, the semiconductor die I has one attachment control element 37 on the inner side 61 of each leg 23 and one on the outer side. The attachment control element 37 on the inner side 61 may be arranged close to the bottom surface 59 and may thus prevent die attach material 7 from contacting the inner sides 67 of the leg 23. Thereby, a membrane 11 may be protected from die attach material 7.

On the side surface 19, the other attachment control element 37 may be a region 69 arranged in a height defining the maximum height 40 and thereby the fillet height 33. Starting from this maximum height 40, the region 69 may extend upwardly along the vertical direction V in order to form the exclusion zone 45.

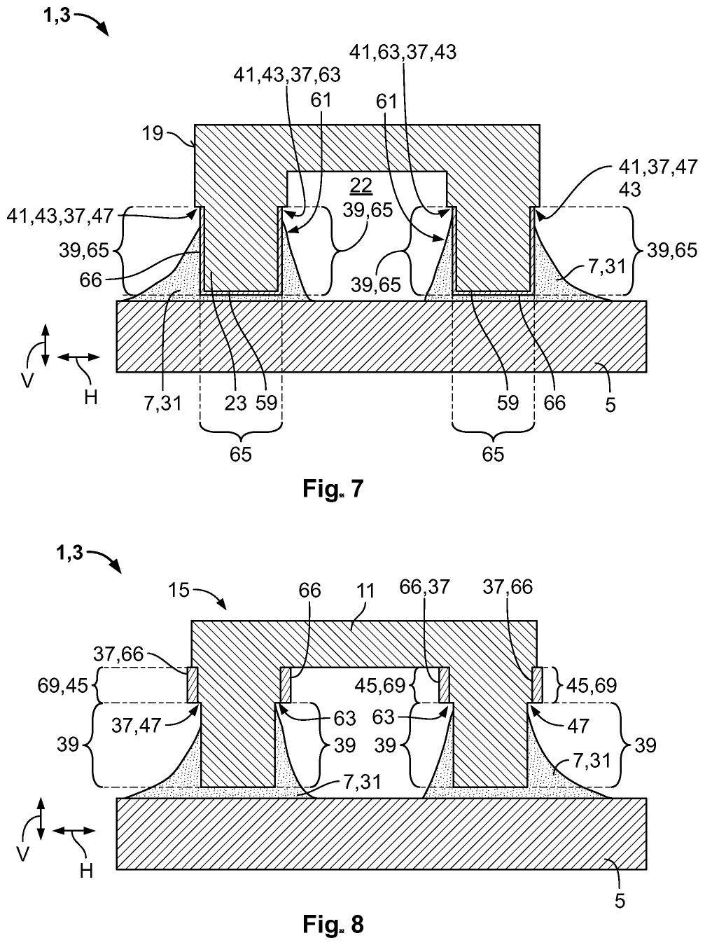

Reference is now made to FIG. 7. The semiconductor die 1 shown in FIG. 7 may have a similar shape in the cross-section to the embodiment described above regarding FIG. 3.

Thus, the legs 23 may each have a step 47 in the side surface 19 and, additionally, an inner step 63 on the inner side 61. In addition to steps 47 and 63, which may act as physical barriers 43 for the die attach material 7, the embodiment shown in FIG. 6 is further provided with functionalized surfaces 66. The functionalized surfaces 66 extend on the bottom surfaces and from there on upwardly along the vertical direction V up to the step 37 on the side surface 19 and to the inner steps 63 on the inner side 61.

Thus, in the cross-sectional view of FIG. 7, the functionalized surface 66 on each leg 23 may have an overall U-shape. The functionalized surface 66 forms a region 65 in the already existing attachment zone 39 formed by the steps 37 and 63. Thereby, the wettability for die attach material 7 in the attachment zone 39 may be further improved.

The functionalized surface 66 may be similar to the functionalized surface 66 described with respect to FIG. 5. Thus, the embodiment shown in FIG. 7 may be regarded as a combination of the embodiments described above with respect to FIGS. 3 and 5.

Another advantageous embodiment of the semiconductor die 1 according to the invention is shown in FIG. 8. This embodiment also utilizes the combination of embodiments described above. Here, the embodiments described with respect to FIGS. 3 and 6 are combined.

A semiconductor die 1 comprising the overall shape as described with respect to FIGS. 3 and 7 is further provided with functionalized surfaces 66. However, in contrast to the embodiment of FIG. 7 described above, the embodiment of FIG. 8 is provided with functionalized surfaces 66 according to the embodiment described with respect to FIG. 6, namely functionalized surfaces 66 that form regions 69 with a reduced wettability for the die attach material 7. Thus, the functionalized surfaces 66 form exclusion zones 45.

The regions 69 are arranged along the vertical direction V upwardly starting from the steps 47 and 63. Thus, the functionalized surfaces 66 may support the already existing attachment control elements 37 formed by steps 47 and 63 in preventing die attach material 7 form spreading upwardly towards the top side 15 of the semiconductor die 1 and in particular from reaching the membrane 11.

It is further possible to provide an embodiment, which combines the embodiments described with respect to FIGS. 7 and 8 above. Thus, two differently functionalized surfaces may be provided: first, functionalized surfaces 66 below the steps 37, 47 and 63 to form regions 69 with improved wettability for die attach material 7 and, second, functionalized surfaces 66 above the steps 47 and 63 to form regions 69 with reduced wettability.

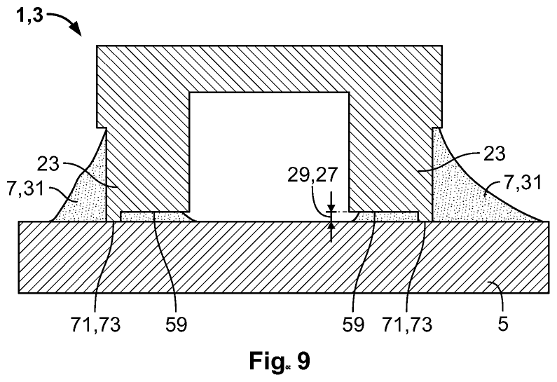

A further advantageous embodiment of the semiconductor die 1 is described with respect to FIG. 9. By way of example, the overall cross-sectional shape of the semiconductor die 1 resembles a semiconductor die 1 as described with respect to FIG. 2. However, this is not mandatory. The semiconductor die I may have any suitable shape.

The semiconductor die 1 in the embodiment of FIG. 9 is provided with spacers 71 on its bottom surface 59. The spacers 71 space the remaining bottom surface 59 apart from the solid structure 5. The term “remaining surfaces 59” refers to regions of the bottom surface 59 that do not comprise the spacers 71. Also in case a spacer 71 is present, the remaining bottom surface 59 may be functionalized and thus configured to increase the wettability with die attach material 7.

Due to the spacers 71, the distance 27 between the bottom surface 59 and the solid structure 5 may be defined. Hence, a well-defined thickness 29 of the die attach material 7 between the bottom surface 59 and the solid structure 5 may be achieved.

The spacers 71 may be shaped as separate feet 73 projecting downwardly from the legs 23, for example four spacers for a rectangular semiconductor die 1.

In the alternative, one or more spacers 71 may be formed as a continuous rib extending along the circumference of the semiconductor die 1. However, in order to achieve even spreading of die attach material 7, the spacers 71 are formed as separate feet 73.

The semiconductor die 1 shown in FIG. 9 may be provided with any of the attachment control elements 37 described above with respect to FIGS. 2 to 8.

A method for attaching the semiconductor die 1 to the solid structure 5 according to the invention comprises the steps of providing a wafer made from at least one semiconducting material, forming at least one attachment control element 37 for at least one die 1, in particular at least one die to be separated from the wafer, separating the wafer into separate semiconductor dies, attaching at least one of the semiconductor dies 1 comprising at least one attachment control element 37 to the solid structure 5 using the die attach material 7. The method steps of forming at least one attachment control element and separating the wafer into separate semiconductor dies may be performed in any order.

The method according to the invention may be further improved in that the membrane 11 with piezoresistive elements is formed into the semiconductor die 1 before separating the wafer into separate dies. The membrane 11 may be formed by etching.

The at least one attach control element 37 may be formed by at least one of the following methods: laser cutting, sawing, etching.

Etching for shaping the attached control element 37, for functionalizing the surface, for forming a membrane 11 and/or for shaping the semiconductor die 1 may be done by at least one of the following methods: reactive ion etching (RIE) and deep reactive ion etching (DRIE). Other methods for layer deposition or etching may be applied depending on the specific application.

In an embodiment, the same method is used for separating the wafer into separate semiconductor dies 1 and for forming the at least one attachment control element 37. This may reduce production costs. Separating the wafer into separate semiconductor dies 1 may be performed by typical dicing methods such as laser cutting, sawing, etching or scribing and snapping.

What is claimed is:

1. A semiconductor die, comprising:
a top side;
a bottom side opposite to the top side; and
a side surface connecting the top side and the bottom side, the bottom side and a part of the side surface are attachable to a solid structure by a die attach material, the side surface has an attachment control element defining:
an attachment zone contacted by the die attach material; and/or
an exclusion zone that is not contacted by the die attach material.

2. The semiconductor die of claim 1, wherein the attachment control element is a stop element that defines a maximum height of the die attach material.

3. The semiconductor die of claim 2, wherein the stop element forms a physical barrier between the attachment zone and the exclusion zone.

4. The semiconductor die of claim 2, wherein the stop element is formed as a step between a pair of vertical sections of the side surface.

5. The semiconductor die of claim 1, wherein the attachment control element is formed as a region with an increased wettability for the die attach material compared to a surface of the semiconductor die in an adjacent region.

6. The semiconductor die of claim 5, wherein the attachment control element is a functionalized surface in the region with the increased wettability.

7. The semiconductor die of claim 1, wherein the attachment control element is formed as a region with a decreased wettability for the die attach material compared to a surface of the semiconductor die in an adjacent region.

8. The semiconductor die of claim 7, wherein the attachment control element is a functionalized surface in the region with the decreased wettability.

9. The semiconductor die of claim 1, wherein the bottom side has a functionalized surface.

10. The semiconductor die of claim 1, wherein the bottom side has a spacer spacing a bottom surface of the semiconductor die apart from the solid structure.

11. The semiconductor die of claim 1, further comprising a membrane.

12. The semiconductor die of claim 1, wherein the semiconductor die has a cross-sectional shape with a pair of legs and a web connecting the legs at a right angle.

13. The semiconductor die of claim 12, wherein the top side forms the web and a pair of outer sides of the legs each have the side surface.

14. A method for attaching a semiconductor die to a solid structure, comprising:
providing a wafer made from a semiconducting material;
forming an attachment control element;
separating the wafer into a plurality of semiconductor dies separate from one another; and
attaching at least one of the semiconductor dies having the attachment control element to a solid structure using a die attach material.

15. The method of claim 14, wherein the attachment control element is formed by at least one of: laser cutting, sawing, and etching.

16. The method of claim 14, wherein a bottom side or a side surface of at least one of the semiconductor dies is functionalized by at least one of: coating, etching, and layer deposition.

17. The method of claim 14, wherein a same process is used for separating the wafer as for forming the attachment control element.

18. A MEMS-sensor device, comprising:
a semiconductor die including:
a top side;
a bottom side opposite to the top side;
a side surface connecting the top side and the bottom side, the bottom side and a part of the side surface are attachable to a solid structure by a die attach material, the side surface has an attachment control element defining:
an attachment zone contacted by the die attach material; and/or
an exclusion zone that is not contacted by the die attach material; and
a membrane containing a plurality of piezoresistive elements.
